(19) United States
(12) Patent Application Publication
(10) Pub. No.: US 2008/0023059 A1
(43) Pub. Date: Jan. 31, 2008

(54) TANDEM SOLAR CELL STRUCTURES AND METHODS OF MANUFACTURING SAME

(76) Inventor: Bulent M. Basol, Manhattan Beach, CA (US)

Correspondence Address: PILLSBURY WINTHROP SHAW PITTMAN LLP, P.O. BOX 10500, MCLEAN, VA, 22102, US

(21) Appl. No.: 11/828,317

(22) Filed: Jul. 25, 2007

Related U.S. Application Data
(63) Continuation-in-part of application No. 11/462,685, filed on Aug. 4, 2006.
(60) Provisional application No. 60/820,323, filed on Jul. 25, 2006.

(51) Int. Cl. H01L 31/042; H01L 31/04

(52) U.S. Cl. 136/244; 136/256

(57) ABSTRACT

The present invention relates to thin film solar cell structures and methods of manufacturing them, particularly tandem cell structures and components thereof. In one aspect there is provided a polycrystalline thin film solar cell structure that is semi-transparent and allows a predetermined wavelength range of light to pass therethrough, in which a bottom semi-transparent conductive layer includes at least one of a ruthenium oxide, an osmium oxide and an iridium oxide. In another aspect there is provided a tandem cell structure in which a top cell bottom contact layer includes at least one of a ruthenium oxide, an osmium oxide and an iridium oxide. In a preferred aspect, the tandem cell structure contains a single contact layer between the absorber layer of the top cell and the absorber layer of the bottom cell. In a particular aspect, this single contact layer is a ruthenium oxide layer.

### CLAIM OF PRIORITY

This application claims priority to U.S. Provisional Appln. Ser. No. 60/820,323 filed Jul. 25, 2006, and also is a continuation-in-part of U.S. application Ser. No. 11/462,685 filed Aug. 4, 2006 entitled “Technique For Preparing Precursor Films And Compound Layers For Thin Film Solar Cell Fabrication”, both of which are incorporated herein in their entirety.

### FIELD OF THE INVENTION

The present invention relates to thin film solar cell structures and methods of manufacturing them.

### BACKGROUND

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods. Group IIB-VIA compounds such as CdTe, Group IBIIIAVIA compounds and amorphous Group IVA materials such as amorphous Si and amorphous Si alloys are important thin film materials that are being developed.

Group IBIIIAVIA compound semiconductors comprising some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ (S_{y}Se_{1-y})_{k, where} 0≦x≦1, 0≦y≦1 and k is approximately 2, have already been employed in solar cell structures that yielded conversion efficiencies approaching 20%. Among the family of compounds, best efficiencies have been obtained for those containing both Ga and In, with a Ga amount in the 15-25%. Recently absorbers comprising Al have also been developed and high efficiency solar cells have been demonstrated using such absorbers.

The structure of a conventional Group IBIIIAVIA compound photovoltaic cell such as a Cu(In,Ga,Al)(S,Se,Te)₂ thin film solar cell is shown in FIG. 1. The device 10 is fabricated on a substrate 11, such as a sheet of glass, a sheet of metal, an insulating foil or web, or a conductive foil or web. The absorber film 12, which comprises a material in the family of Cu(In,Ga,Al)(S,Se,Te)₂, is grown over a conductive layer 13 or a contact layer, which is previously deposited on the substrate 11 and which acts as the electrical ohmic contact to the device. The most commonly used contact layer or conductive layer in the solar cell structure of FIG. 1 is Molybdenum (Mo). If the substrate itself is a properly selected conductive material such as a Mo foil, it is possible not to use a conductive layer 13, since the substrate 11 may then be used as the ohmic contact to the device. The conductive layer 13 may also act as a diffusion barrier in case the metallic foil is reactive. For example, foils comprising materials such as Al, Ni, Cu may be used as substrates provided a barrier such as a Mo layer is deposited on them protecting them from Se or S vapors. The barrier is often deposited on both sides of the foil to protect it well. After the absorber film 12 is grown, a transparent layer 14 such as a CdS, ZnO or CdS/ZnO stack is formed on the absorber film. Radiation 15 enters the device through the transparent layer 14. Metallic grids (not shown) may also be deposited over the transparent layer 14 to reduce the effective series resistance of the device. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side. A variety of materials, deposited by a variety of methods, can be used to provide the various layers of the device shown in FIG. 1.

CdTe solar cell structure is typically a superstrate structure that is obtained by first depositing a transparent conductive layer (TCL) on a transparent substrate such as glass, and then depositing layers of CdS, CdTe and an ohmic contact. The ohmic contact is traditionally a metallic contact such as Ni or an ink deposited material comprising graphite. A small amount of Cu is also traditionally added to the ohmic contact composition to improve its performance. CdTe solar cells with above 16% conversion efficiency have been demonstrated with such structures.

Multi-junction stacked solar cells or tandem cells of amorphous or polycrystalline thin film materials are believed to have great potential for very high conversion efficiencies in excess of 20%. However, manufacturing such complex structures presents many challenges.

FIGS. 2 and 3 are general representations of four-terminal and two-terminal tandem cell structures, respectively. The four-terminal device of FIG. 2 comprises two solar cells, a larger-bandgap top cell 20 and a smaller-bandgap bottom cell 21. Although it is possible to add one or more solar cells to the bottom of the stacks of FIG. 2 and FIG. 3, wherein each additional cell has a comparatively lower bandgap than the one above it, we will continue to describe the concepts of the present invention using the two cell stacks. The top cell 20 has a top cell top contact 22 and a top cell bottom contact 24. Top cell absorber and junction area are in a top cell region 23. The bandgap of the absorber in the top cell region 23 may be in the range of 1.3-2.5 eV or higher. Top cell top fingers 25 and top cell bottom fingers 26 are formed on the top cell top contact 22 and the top cell bottom contact 24 respectively, to reduce effective series resistance. The bottom cell 21 has a bottom cell top contact 29 and a bottom cell bottom contact 31. Bottom cell absorber and junction area are in a bottom cell region 30. The bandgap of the absorber in the bottom cell region 30 may be in the range of 0.8-1.4 eV or lower. Bottom cell top fingers 28 are formed on the bottom cell top contact 29. An insulating or high resistivity buffer layer 27 may be formed between the two cells to physically attach the two and improve the optical coupling between them.

During operation, radiation enters the tandem structure through the top cell top contact 22 which is transparent. The top cell region 23 absorbs a portion of the radiation (depending upon the bandgap value) and generates power, while radiation that is not absorbed (longer wavelength radiation) passes through the top cell bottom contact 24 and the buffer layer 27, which are transparent to the wavelengths passing through it. Longer wavelength radiation then enters the bottom cell through the transparent bottom cell top contact 29, gets absorbed within the bottom cell region 30 and creates additional power. It should be noted that, the bottom cell bottom contact 31 does not have to be transparent since there is no lower cell in the stack of FIG. 2 for radiation to pass through to.

The tandem device structure of FIG. 2 has four terminals. There is no internal electrical connection between the two devices. The top cell power is accessed through two terminals (not shown) connected to the top cell top fingers 25 and the top cell bottom fingers 26. The bottom cell power is accessed through two terminals (not shown) connected to the bottom cell top fingers 28 and the bottom cell bottom contact 31.

In the two-terminal tandem structure of FIG. 3, the large-bandgap cell 35 and the small-bandgap cell 36 are electrically connected in a series manner so that the voltage obtained between the two terminals (not shown), one connected to the large-bandgap cell top fingers 25 and the other connected to the small-bandgap cell bottom contact 31, is the sum of voltages generated by the large-bandgap cell 35 and the small-bandgap cell 36. The current passing through the two terminals, on the other hand, is the same for both cells. The most important difference between the structure in FIG. 3 and the structure in FIG. 2 is the presence of a conductive interconnect region 38 in the two-terminal design, between the large-bandgap cell bottom contact 37 and the small-bandgap cell top contact 29 both of which are transparent. The interconnect region 38 should not be introducing a high resistance to the overall device. Otherwise, power loss due to this excess resistance would reduce the conversion efficiency.

Polycrystalline thin film materials suitable for large-bandgap or top cell applications include various large bandgap amorphous Si alloys, and compounds such as (Cd,Zn)Te and Cu(In,Ga,Al)(Se,S)₂. Bottom cell or small-bandgap cell materials include, but are not limited to amorphous Si—Ge alloys, and compounds such as (Hg,Cd)Te and Cu(In,Ga)Se₂. Relationships between the top cell bandgap and the bottom cell bandgap for best device efficiency are well established and published. These bandgaps may be adjusted by tailoring the composition of the solar cell absorbers. For example, by changing the Zn content in CdTe from 0% to 100%, the bandgap of the top cell may be changed from about 1.45 eV to about 2.26 eV. Similarly, by increasing the Ga and/or Al and/or S amount in a Cu(In,Ga,Al)(S,Se)₂ absorber, bandgap values as high as 2.5 eV may be reached. For the bottom cells, addition of Hg reduces the bandgap of CdTe from 1.5 eV to a lower value which may be adjusted to a 0.7-1.2 eV range or even lower. CuInSe₂ or CuInTe₂ with or without a small amount of Ga (up to about 30%) is a good bottom cell material with a bandgap value that can be adjusted in the range of 0.95-1.2 eV.

One important challenge in manufacturing the tandem solar cell structures such as those shown in FIGS. 2 and 3 is the fabrication of the top cell with a high quality, large band-gap top cell bottom contact. Back contacts for solar cell structures are typically metallic and they do not transmit light. For stacked cell applications various research groups have been working on developing transparent back contacts. In addition to fabrication of a conductive and transparent back contact, in the case of the two terminal device of FIG. 3, there is also the challenge of processing the top cell directly onto the bottom cell. Reactive atmospheres, high temperatures etc. needed for top cell fabrication often negatively impact the bottom cell. We will now give examples demonstrating some of these prior-art challenges.

Let us take, as an example, a CuGaSe₂ solar cell as the top cell of a four terminal tandem device structure. Fabrication of such a top cell requires the growth of CuGaSe₂ absorber layer on a transparent and conductive contact layer. The standard back contact material for the CuGaSe₂ device structure is Mo, which of course, would not be suitable for this application because it is not transparent. There have been attempts to grow CuGaSe₂ thin films on well known transparent conductive layers such as SnO₂ (TO), Indium-Tin-Oxide (ITO), and ZnO (ZO), however, chemical interactions between these materials and the constituents of the growing CuGaSe₂ layer affected solar cell parameters negatively. If, for example, the CuGaSe₂ is grown by co-evaporation of Cu, Ga and Se on a heated glass substrate coated with at least one of TO, ITO and ZO, a certain degree of intermixing between the growing absorber material and the conductive oxide is observed. These conductive oxides also react with Se forming phases such as Zn-selenide, In-selenide and tin-selenide, which deteriorate the ohmic nature of the conductive oxide/CuGaSe₂ interface. If the CuGaSe₂ is grown by two stage techniques, such as by depositing a metallic Cu—Ga layer on the surface of a tin-oxide (TO), indium-tin-oxide (ITO) or doped zinc-oxide (ZO) layer and then selenizing it with selenium vapor or H₂Se gas at temperatures in the range of 400-550 C, interactions between the conductive oxide layers and Cu, Ga and Se during the CuGaSe₂ film formation cause similar problems and deteriorate the ohmic back contact.

The above example discussed difficulties associated with growing a selenide absorber layer on a transparent base comprising a substrate (such as glass) and a transparent back contact (such as TO, ITO and ZO). It should be appreciated that if this selenide layer was grown on an already formed small-bandgap solar cell such as a CuInSe₂ solar cell, to form a two terminal stack shown in FIG. 3, similar concerns would apply.

As the brief review above demonstrates, there is a need to develop highly stable transparent conductive contact materials to be used in thin film solar cell structures including tandem cell structures.

### SUMMARY OF THE INVENTION

The present invention relates to thin film solar cell structures and methods of manufacturing them, particularly tandem cell structures and components thereof.

In one aspect there is provided a polycrystalline thin film solar cell structure comprising a polycrystalline thin film absorber layer with a bottom surface and a top surface through which light enters the absorber layer; and a semi-transparent conductive layer including at least one of a ruthenium oxide, an osmium oxide and an iridium oxide, wherein the semi-transparent conductive layer makes physical contact with the bottom surface of the absorber layer, and wherein the polycrystalline thin film solar cell structure is semi-transparent and allows a predetermined wavelength range of light to pass therethrough.

In another aspect there is provided a tandem cell structure in which a top cell bottom contact layer includes at least one of a ruthenium oxide, an osmium oxide and an iridium oxide. In a preferred aspect, the tandem cell structure contains a single contact layer between the absorber layer of the top cell and the absorber layer of the bottom cell. In a particular aspect, this single contact layer is a ruthenium oxide layer.

### BRIEF DESCRIPTION OF THE DRAWINGS

FIG. 1 is a cross-sectional view of a solar cell employing a Group IBIIIAVIA absorber layer.

FIG. 2 is a four terminal tandem device structure.

FIG. 3 is a two terminal tandem device structure.

FIG. 4 is a thin film solar cell structure using at least one contact including RuO₂.

FIG. 5 is tandem device structure according to one embodiment of the present invention.

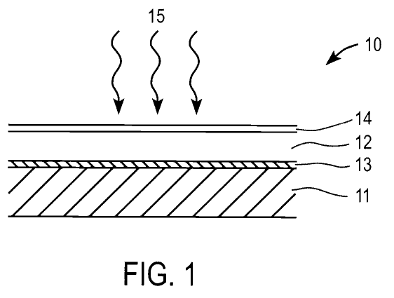

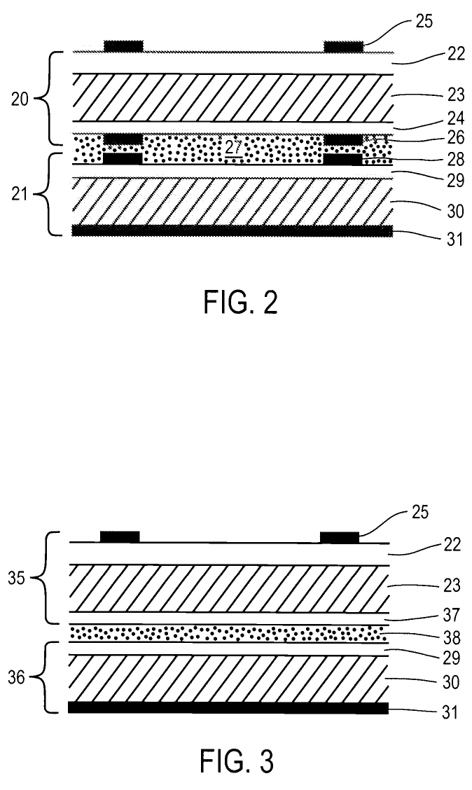

### DETAILED DESCRIPTION

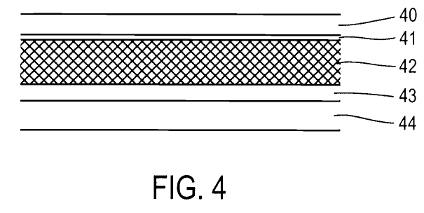

FIG. 4 shows a solar cell structure fabricated in accordance with an embodiment of the present invention. The solar cell comprises a transparent top contact 40, a buffer layer 41, an absorber layer 42, a transparent back contact layer 43 and a transparent substrate 44.

For a Group IIBVIA compound cell, the transparent top contact 40 may comprise at least one of TO, ZO, ITO, Cadmium-stannate or other well known transparent conductive materials. The buffer layer may comprise materials such as (Cd,Zn)S, ZnSe etc. The absorber layer 42 may be Group IIBVIA material such as (Cd,Zn)Te, (Cd,Mn)Te, (Cd,Mg)Te etc.

For a Group IBIIIAVIA compound cell, the transparent top contact 40 may comprise at least one of TO, ZO, ITO, Cadmium-stannate or other well known transparent conductive materials. The buffer layer may comprise materials such as (Cd,Zn)S, In(S,O), In(Se,O), Zn(Se,S) etc. The absorber layer 42 may be a Group IBIIIAVIA material such as a (Cu,Ag)(In,Ga,Al) (S,Se,Te)₂ layer.

The transparent back contact layer 43 of FIG. 4 comprises an oxide of a material selected from the group of Ru, Ir and Os, preferably Ru. Ru-oxide (RuO₂) is inert, therefore can withstand corrosion in a Se, S or Te atmosphere at high temperatures of 400-600 C. It is highly conductive and transparent. One unique property of oxides of Ru, Os and Ir is that they have metallic conductivity, resistivity values being in the 10⁻⁵-10⁻⁶ ohm-cm range. Therefore, very thin transparent layers (such as 5-20 nm thick layers) of such materials provide reasonably low sheet resistance (such as 0.1-50 ohms/square). Additionally, RuO₂ does not chemically react with the constituents of solar cell absorber materials to any appreciable level, constituents being Cu, In, Ga, Al, Cd, Zn etc. Therefore, a Group IBIIIAVIA material or a Group IIBVIA material may be grown on a surface comprising RuO₂, without adversely affecting the interface or ohmic contact between the growing absorber layer and the surface comprising RuO₂. It should be noted that the transparent back contact layer 43 may be pure RuO₂ or it may comprise alloys or mixtures of RuO₂ with other transparent materials such as ITO, TO, ZO etc. The transparent back contact layer 43 may also comprise several sub-layers each containing one or more transparent material. For example, the transparent back contact layer 43 may have a structure of A/B where the “A” sub-layer may be a transparent conductive oxide (TCO) such as ZO, ITO or TO and the “B” sub-layer comprises RuO₂. In this case the solar cell absorber is deposited on the surface of the “B” sub-layer. Such a structure utilizes the high conductivity of the well established TCO's and the inertness of RuO₂. In other words, a transparent layer comprising RuO₂ is used to protect the underlying TCO's during the deposition of the absorber layer. The thickness of the transparent back contact layer may be in the range of 2-200 nm, preferably 10-100 nm if it is in the form a homogenous single layer. If it comprises two or more sub-layers, the RuO₂-containing sub-layer thickness may be in the range of 10-100 nm, whereas the total thickness of the transparent back contact layer may be much higher, such as in the range of 100-500 nm, or even more depending on the sheet resistance requirement of the device design. It should be noted that finger patterns (not shown) may be deposited on the transparent top contact 40 and/or the transparent back contact layer 43 to further reduce the series resistance of the cell.

We will now describe how a solar cell with a transparent back contact may be fabricated as a top cell in a four terminal tandem structure using the teachings of this invention. We will use a device employing a Group IBIIIAVIA compound absorber layer as an example. Solar cells employing Group IIBVIA compounds such as CdTe may also be produced in similar fashion.

### EXAMPLE 1

A glass sheet or transparent polymeric foil (such as polyimide) may be used as the substrate. A transparent conductive oxide (TCO) layer, such as ZO, ITO, TO etc., may then be deposited on the substrate. The thickness of the TCO layer may be in the range of 50-500 nm, the thickness being determined by the design of the device and the current carrying capacity needed. A RuO₂ film may be deposited over the TCO layer. Thickness of the RuO₂ film may be in the range of 2-200 nm, preferably in the range of 10-100 nm. This film may be deposited by various techniques such as evaporation, sputtering, reactive sputtering, reactive evaporation, activated reactive evaporation, oxidation of Ru films, MOCVD, electrodeposition, ink deposition etc. A thin film polycrystalline Cu(In,Ga)(S,Se)₂ absorber layer may then be deposited on the RuO₂ surface by various techniques well known in the field. These techniques include but are not limited to sputtering, co-evaporation, electrodeposition, ink deposition, screen printing, MOCVD, two-stage processing (deposition of a precursor layer comprising at least two of Cu, In, Ga, Se, S and then reaction of the precursor layer constituents with each other and optionally with species introduced from a reaction atmosphere to form the compound), reactive sputtering etc. The thickness of the absorber layer may be in the range of 0.4-10 um, preferably in the range of 0.7-5 um, thinner absorber layers being more appropriate for top cell structure in a tandem device configuration. Once the absorber layer is deposited, a buffer layer of CdS, CdZnS, In—Se—O, ZnSe, undoped ZnO etc. may be deposited on the absorber layer. A TCO layer may then be formed over the buffer layer as the top transparent contact. It should be noted that RuO₂ may also be effectively used as a buffer layer directly on the absorber layer. Prior art work has shown that a Cd-free buffer layer such as undoped ZnO may be used in Cu(In,Ga)(Se,S)₂ solar cell structure yielding high conversion efficiency. However, such devices show poor stability and/or time dependent variations in the conversion efficiency. As a highly stable transparent oxide RuO₂ may provide stable performance in a device structure comprising “back contact/Cu(In,Ga)(Se,S)₂/RuO₂/TCO” stack. The back contact, as explained above, may also contain RuO₂. Furthermore, the top contact TCO may also comprise RuO₂. There may also be finger patterns formed over the TCO layer.

### EXAMPLE 2

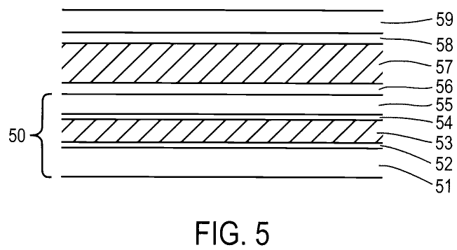

A large bandgap thin film Cu(In,Ga)(S,Se)₂ top cell may be directly fabricated on a bottom cell to form a two-terminal device using the teachings of this invention. In this case, referring to FIG. 5, the base is an already formed bottom cell 50, which may be a thin film CuInSe₂ device fabricated on a transparent or non-transparent substrate 51. The general structure of the bottom cell 50 may be “substrate 51/bottom cell contact 52/CuInSe₂ layer 53 or bottom cell absorber/bottom cell buffer layer 54/bottom cell TCO layer 55” with an optional finger pattern (not shown) on the bottom cell TCO layer 55. A RuO₂ film 56 may be deposited over the bottom cell TCO layer 55. Thickness of the RuO₂ film 56 may be in the range of 2-200 nm, preferably 5-100 nm, most preferably 5-20 nm. This film may be deposited by various techniques such as evaporation, sputtering, reactive sputtering, reactive evaporation, activated reactive evaporation, oxidation of Ru films, MOCVD, electrodeposition, ink deposition etc. It should be noted that the bottom cell TCO layer 55 may not be used in the structure of FIG. 5. In this case the RuO₂ film 56 acts as a transparent top contact for the bottom cell 50 when it is deposited on the bottom cell buffer layer 54. A large-bandgap top cell absorber layer 57, such as a Cu(In,Ga)(S,Se)₂ layer, may then be deposited on the RuO₂ film 56 surface by various techniques well known in the field. These techniques include but are not limited to sputtering, co-evaporation, electrodeposition, ink deposition, screen printing, MOCVD, two-stage processing (deposition of a precursor layer comprising at least two of Cu, In, Ga, Se, S and then reaction of the precursor layer constituents with each other and optionally with species introduced from a reaction atmosphere to form the compound), reactive sputtering etc. The thickness of the top cell absorber layer 57 may be in the range of 0.4-10 um, preferably in the range of 0.7-5 um, thinner absorber layers being more appropriate for top cell structure in a tandem device configuration. Once the top cell absorber layer 57 is deposited, a top cell buffer layer 58 such as a CdS, CdZnS, In—Se—O, ZnSe, undoped ZnO etc. layer may be deposited on the top cell absorber layer 57. A top cell TCO layer 59 may then be formed over the top cell buffer layer 58 as the top transparent contact. It should be noted that a RuO₂ layer (not shown) may also be effectively used as a top cell buffer layer directly on the top cell absorber layer 57 as well as on the CuInSe₂ layer 53 of the bottom cell 50.

Prior-art work has shown that a Cd-free buffer layer such as undoped ZnO may be used in Cu(In,Ga)(Se,S)₂ solar cell structure yielding high conversion efficiency. However, such devices show poor stability and/or time dependent variations in the conversion efficiency. As a highly stable transparent oxide RuO₂ may provide stable performance in a device structure comprising “back contact/Cu(In,Ga)(Se,S)₂/RuO₂/TCO” stack. The back contact, as explained above, may also contain RuO₂. Furthermore, the top contact TCO may also comprise RuO₂. Use of RuO₂ as a buffer layer in the bottom cell may improve stability of the bottom cell which is exposed to high temperatures (typically 400-550 C) and reactive atmosphere (typically Se and/or S atmospheres) during the formation of the large-bandgap absorber layer of the top cell.

It should be noted that during the fabrication of the solar cells described above, part of the RuO₂ at the absorber/RuO₂ interface may react with a Group VIA material such as S and Se forming a very thin layer (typically 1-20 nm) of Ru—Se or Ru—S or Ru—Se—S. If the RuO₂ thickness itself is small, such as 2-30 nm, then substantially all of RuO₂ may turn into Ru—Se or Ru—S or Ru—Se—S. Even in this case, RuO₂ containing bottom contact of a top cell performs well as a transparent contact because the selenized and sulfurized layer thicknesses are extremely small and they behave like semiconductors with bandgaps, unlike metallic compounds. Therefore, they are still transparent to the infrared radiation that passes through them.

The examples above described fabrication of substrate-type solar cells. As will be apparent to those skilled in the art the solar cell structures of the above examples may be reversed to fabricate superstrate-type solar cells also using the present invention. Also concepts were described with Ru as an example. It should be understood that oxides of Ir and/or Os may also be used in the present invention.

What is claimed is:

1. A polycrystalline thin film solar cell structure comprising:
a polycrystalline thin film absorber layer with a bottom surface and a top surface through which light enters the absorber layer; and
a semi-transparent conductive layer including at least one of a ruthenium oxide, an osmium oxide and an iridium oxide, wherein the semi-transparent conductive layer makes physical contact with the bottom surface of the absorber layer, and wherein the polycrystalline thin film solar cell structure is semi-transparent and allows a predetermined wavelength range of light to pass therethrough.

2. The structure according to claim 1 wherein the absorber layer thickness is less than 10 um.

3. The structure according to claim 2 wherein the polycrystalline thin film absorber layer is a Group IBIIIAVIA semiconductor layer.

4. The structure according to claim 3 wherein the semi-transparent conductive layer includes at least two sub-layers and at least one of the sub-layers includes ruthenium oxide.

5. The structure according to claim 4 wherein at least one of the sub-layers includes a transparent conductive oxide including at least one of Zn, In, Sn and Cd.

6. The structure according to claim 5 wherein the semi-transparent conductive layer is a RuO₂/TCO stack, wherein the RuO₂ in the RuO₂/TCO stack makes physical contact with the bottom surface of the absorber layer and wherein the TCO in the RuO₂/TCO stack is at least one of tin-oxide, indium-tin-oxide and zinc-oxide.

7. The structure according to claim 3 wherein the semi-transparent conductive layer is a ruthenium oxide layer.

8. The structure according to claim 7 wherein a thickness of the ruthenium oxide layer is in the range of 5-20 nm.

9. The structure according to claim 1 wherein the semi-transparent conductive layer includes at least two sub-layers and at least one of the sub-layers includes ruthenium oxide.

10. The structure according to claim 9 wherein at least one of the sub-layers includes a transparent conductive oxide including at least one of Zn, In, Sn and Cd.

11. The structure according to claim 10 wherein the semi-transparent conductive layer is a RuO₂/TCO stack, the RuO₂ in the RuO₂/TCO stack making physical contact with the bottom surface of the absorber layer and wherein the TCO in the RuO₂/TCO stack is at least one of tin-oxide, indium-tin-oxide and zinc-oxide.

12. A tandem solar cell structure comprising,
a top cell that is semi-transparent and allows a predetermined wavelength range of light to pass therethrough, the top cell including a semi-transparent top cell top contact layer, a top cell absorber layer and a semi-transparent top cell bottom contact layer, wherein the semi-transparent top cell bottom contact layer includes at least one of a ruthenium oxide, an osmium oxide and an iridium oxide; and
a bottom cell disposed below the top cell, the bottom cell absorbing the predetermined wavelength range of light.

13. The structure according to claim 12 wherein the bottom cell includes a semi-transparent bottom cell top contact layer, a bottom cell absorber layer and a bottom cell bottom contact layer; and
an interface material layer that physically connects together the top cell bottom contact layer and the bottom cell top contact layer.

14. The structure according to claim 13 wherein the interface material layer is conductive and electrically connects together the top cell bottom contact layer and the bottom cell top contact layer.

15. The structure according to claim 13 wherein the interface material is an insulating layer that contains top cell bottom fingers and bottom cell top fingers disposed therein.

16. The structure according to claim 12 wherein the bottom cell includes a bottom cell absorber layer and a bottom cell bottom contact layer; and
wherein a contact layer of the bottom cell is provided by the bottom cell bottom contact layer.

17. The structure according to claim 16 wherein the bottom cell bottom contact layer is a ruthenium oxide layer.

18. The structure according to claim 12 wherein the top cell absorber layer is a Group IBIIIAVIA semiconductor.

19. The structure according to claim 18 wherein the bottom cell absorber layer is a Group IBIIIAVIA semiconductor.

20. The structure according to claim 12 wherein the top cell bottom contact layer includes at least two sub-layers and at least one of the sub-layers includes ruthenium oxide.

21. The structure according to claim 20 wherein at least one of the sub-layers includes a transparent conductive oxide including at least one of Zn, In, Sn and Cd.

22. The structure according to claim 20 wherein the bottom cell top contact layer includes at least two sub-layers and at least one of the sub-layers includes ruthenium oxide.

23. The structure according to claim 22 wherein at least one of the sub-layers of the bottom cell top contact layer includes a semi-transparent conductive oxide including at least one of Zn, In, Sn and Cd.
